(19) United States
(12) Patent Application Publication
(10) Pub. No.: US 2025/0159959 A1
(43) Pub. Date: May 15, 2025

(54) NITRIDE STRUCTURE AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hajime NAGO, Yokohama (JP); Hisashi YOSHIDA, Kawasaki (JP); Jumpei TAJIMA, Mitaka (JP); Toshiki HIKOSAKA, Kawasaki (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/655,442

(22) Filed: May 6, 2024

(30) Foreign Application Priority Data
Nov. 10, 2023 (JP) 2023-192301

(51) Int. Cl. H01L 29/207; H01L 29/04; H01L 29/20; H01L 29/205; H01L 29/778

(52) U.S. Cl. CPC H10D 62/854; H10D 30/4755; H10D 62/40; H10D 62/824; H10D 62/8503

(57) ABSTRACT

According to one embodiment, a nitride structure includes a stacked body. The stacked body includes a base including silicon, a first nitride region including AlN, and a second nitride region including Al_{z2}Ga_{1-z2}N (0≤z2<1). The first nitride region is provided between the base and the second nitride region in a first direction. The stacked body includes a first interface region including a first interface between the base and the first nitride region. The first interface region includes a first peak position in the first direction. A chlorine concentration profile along the first direction in the stacked body has a chlorine peak value at the first peak position.

### CROSS-REFERENCE TO RELATED APPLICATIONS

This application is based upon and claims the benefit of priority from Japanese Patent Application No. 2023-192301, filed on Nov. 10, 2023; the entire contents of which are incorporated herein by reference.

### FIELD

Embodiments described herein relate generally to a nitride structure and a semiconductor device.

### BACKGROUND

For example, improved characteristics are desired in semiconductor devices based on nitride structures.

### BRIEF DESCRIPTION OF THE DRAWINGS

FIG. 1 is a schematic cross-sectional view illustrating a nitride structure according to a first embodiment;

FIG. 2 is a graph illustrating the nitride structure according to the first embodiment;

FIG. 3 is a schematic cross-sectional view illustrating a nitride structure according to the first embodiment;

FIG. 4 is a graph illustrating the characteristics of nitride structures;

FIG. 5 is a graph illustrating the characteristics of the nitride structures;

FIG. 6 is a schematic cross-sectional view illustrating a semiconductor device according to a second embodiment; and

FIG. 7 is a schematic cross-sectional view illustrating a semiconductor device according to the second embodiment.

### DETAILED DESCRIPTION

According to one embodiment, a nitride structure includes a stacked body. The stacked body includes a base including silicon, a first nitride region including AlN, and a second nitride region including Al_{z2}Ga_{1-z2}N (0≤z2<1). The first nitride region is provided between the base and the second nitride region in a first direction. The stacked body includes a first interface region including a first interface between the base and the first nitride region. The first interface region includes a first peak position in the first direction. A chlorine concentration profile along the first direction in the stacked body has a chlorine peak value at the first peak position.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

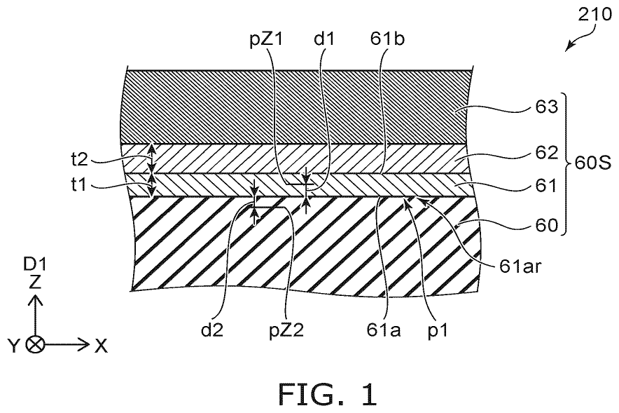

FIG. 1 is a schematic cross-sectional view illustrating a nitride structure according to a first embodiment.

As shown in FIG. 1, the nitride structure 210 according to the embodiment includes a stacked body 60S. The stacked body 60S includes a base 60, a first nitride region 61, and a second nitride region 62.

The base 60 includes silicon. The base 60 is, for example, a silicon substrate.

The first nitride region 61 includes AlN. The first nitride region 61 is, for example, an AlN layer.

The second nitride region 62 includes Al_{z2}Ga_{1-z2}N (0≤z2<1). The second nitride region 62 is an AlGaN layer. The composition ratio z2 is, for example, not less than 0.1 and not more than 0.3.

The first nitride region 61 is provided between the base 60 and the second nitride region 62 in a first direction D1. The first direction D1 is defined as a Z-axis direction. One direction perpendicular to the Z-axis direction is defined as an X-axis direction. A direction perpendicular to the Z-axis direction and the X-axis direction is defined as a Y-axis direction. The base 60 is layered along the X-Y plane. The first nitride region 61 and the second nitride region 62 are layered along the X-Y plane.

As shown in FIG. 1, the stacked body 60S may further include a third nitride region 63. The second nitride region 62 is between the first nitride region 61 and the third nitride region 63. The third nitride region 63 includes, for example, Al, Ga, and N (nitrogen).

The stacked body 60S includes a first interface 61a between the base 60 and the first nitride region 61. The stacked body 60S includes a first interface region 61ar including the first interface 61a.

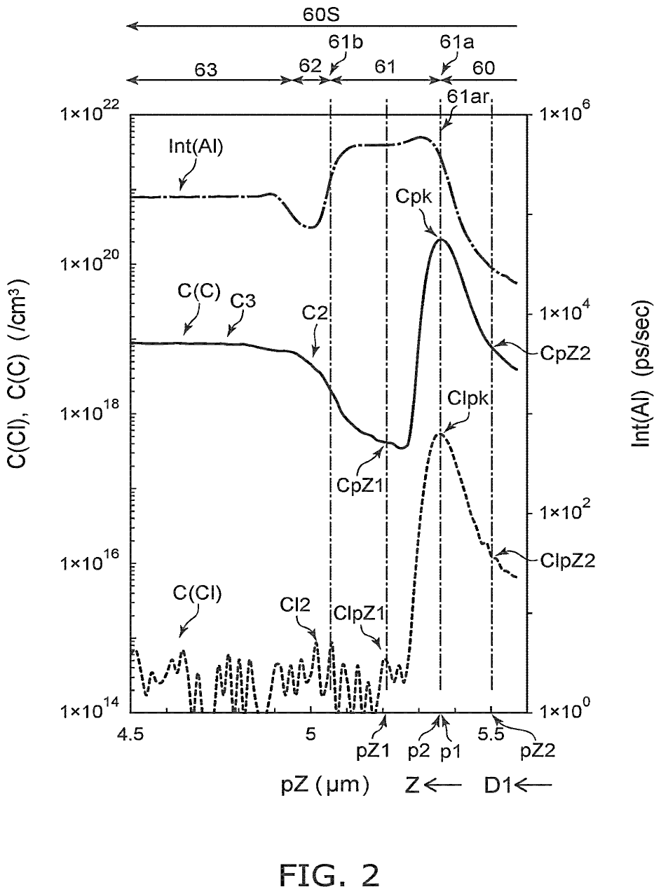

FIG. 2 is a graph illustrating the nitride structure according to the first embodiment.

FIG. 2 shows an example of the element profile in the stacked body 60S. FIG. 2 illustrates the results of SIMS (Secondary Ion Mass Spectrometry) analysis of the stacked body 60S. The horizontal axis in FIG. 2 is a position pZ in the thickness direction. The left vertical axis in FIG. 2 is the concentration C (Cl) of Cl (chlorine) and the concentration C (C) of C (carbon). The right vertical axis in FIG. 2 is the detected intensity of Al Int (Al).

As shown in FIG. 2, the first interface region 61ar including the first interface 61a includes a first peak position p1. The chlorine concentration profile along the first direction D1 in the stacked body 60S has a chlorine peak value Clpk at the first peak position p1. The first peak position p1 is the position of the first interface 61a or a position near the first interface 61a.

By the chlorine concentration having a peak at the first peak position p1, high crystal quality can be obtained. For example, dislocation density can be reduced. According to the embodiment, a nitride structure with improved characteristics can be provided.

By providing the first nitride region 61 including AlN on the base 60 including silicon, the first nitride region 61 with high quality can be obtained. For example, in a first reference example in which a layer including Ga is provided on the base 60 including silicon, it is difficult to obtain a good layer due to the reaction between Ga and silicon.

In a case where the first nitride region 61 including AlN is formed on the base 60 including silicon, nitrogen or molecules including nitrogen (for example, ammonia, etc.) may be attached to the surface of the silicon. In this case, nitrogen and silicon may combine to form a thin island-like SiN region or the like. In this case, the crystal quality of the AlN layer above it is low due to the SiN region. For example, the surface flatness of the AlN layer is low. Therefore, it is difficult to obtain high crystallinity also in the second nitride region 62 above the first nitride region 61 of AlN.

In the embodiment, as described above, the chlorine concentration is locally increased at the first peak position p1 (at the first interface 61a or near the first interface 61a). Thereby, the formation of SiN region is suppressed. By forming the first nitride region 61 of AlN on the surface where the SiN region is not substantially formed, the first nitride region 61 having high surface flatness and high crystal quality is obtained. As a result, high surface flatness and high crystal quality can be obtained in the second nitride region 62.

In one example, the adhesion of nitrogen to the silicon surface may be caused by nitrogen (or nitrogen-including molecules) remaining on an inner wall surface of the film forming apparatus leaving the inner wall surface. In such a case, it is effective to clean the inside of the film forming apparatus with a gas including chlorine (for example, hydrogen chloride) before forming the first nitride region 61. Thereby, nitrogen (or nitrogen-including molecules) remaining on the inner wall surface can be removed. At this time, chlorine may remain on the inner wall surface after cleaning with a gas including chlorine, and the chlorine may adhere to the surface of the silicon. By forming an AlN layer on the silicon surface to which chlorine is attached, the chlorine concentration C(Cl) may be locally increased at the first interface 61a. In forming the AlN layer in this case, for example, a source gas including Al may be introduced before introducing other source gases. The formation of SiN regions is more effectively suppressed.

In another example, for example, before forming the AlN layer (the first nitride region 61), the base 60 including silicon may be subjected to heat treatment in an atmosphere including chlorine. Thereby, formation of a SiN region on the silicon surface can be suppressed. This results in a crystalline AlN layer. High surface flatness can be obtained. Even in such an example, the chlorine concentration C (Cl) may locally increase at the first interface 61a.

As shown in FIG. 2, in this example, the chlorine peak value Clpk at the first peak position p1 is approximately 7×10¹⁷/cm³. In the embodiment, the chlorine peak value Clpk may be, for example, not less than 2×10¹⁷/cm³ and not more than 2×10¹⁸/cm³.

In the embodiment, it is preferable that the chlorine concentration C (Cl) is locally high at the first interface 61a, and the chlorine concentration C (Cl) is low in other regions (for example, in the AlN layer).

As shown in FIG. 1, the stacked body 60S includes a second interface 61b between the first nitride region 61 and the second nitride region 62. The first nitride region 61 includes a first position pZ1. The first position pZ1 is the center between the first interface 61a and the second interface 61b in the first direction D1. For example, the first position pZ1 is between the first peak 30 position p1 and the second interface 61b in the first direction D1.

As shown in FIG. 2, the chlorine concentration ClpZ1 at the first position pZ1 is lower than the chlorine peak value Clpk. For example, the concentration ClpZ1 at the first position pZ1 may be not less than 1/1000 times and not more than 1/100 times the chlorine peak value Clpk. The concentration ClpZ1 of chlorine at the first position pZ1 may be, for example, not less than 1×10¹³/cm³ and not more than 2×10¹⁵/cm³. Thus, the chlorine concentration C (Cl) is locally high at the first peak position p1 (at the first interface 61a or near the first interface 61a) and steeply decreases in the first nitride region 61.

As described above, by the chlorine concentration C (Cl) being locally high at the first interface 61a, the formation of the SiN region is effectively suppressed. As a result, high crystal quality can be obtained in the first nitride region 61. Furthermore, by the chlorine concentration C (Cl) sharply decreasing in the first nitride region 61, further higher crystal quality can be obtained in the first nitride region 61.

As shown in FIG. 1, the stacked body 60S may include the second interface 61b between the first nitride region 61 and the second nitride region 62. The base 60 includes a second position pZ2. On the other hand, as already explained, the first nitride region 61 includes the first position pZ1. The first position pZ1 is the center between the first interface 61a and the second interface 61b in the first direction D1. The direction from the second position pZ2 to the first position pZ1 is along the first direction D1. A distance along the first direction D1 between the second position pZ2 and the first peak position p1 is defined as a distance d2. A distance along the first direction D1 between the first peak position p1 and the first position pZ1 is defined as a distance d1. The distance d2 is the same as the distance d1.

As shown in FIG. 2, the chlorine concentration ClpZ1 at the first position pZ1 is lower than a chlorine concentration ClpZ2 at the second position pZ2. Thus, the chlorine concentration C (Cl) may decrease more steeply in the first nitride region 61 than in the base 60. Higher crystal quality is obtained in the first nitride region 61.

As shown in FIG. 2, the chlorine concentration CI2 in the second nitride region 62 is lower than the chlorine peak value Clpk. The chlorine concentration CI2 in the second nitride region 62 is, for example, 1×10¹⁵/cm³ or less. For example, the chlorine peak value Clpk is not less than 100 times and not more than 5000 times the chlorine concentration CI2 in the second nitride region 62. By the chlorine concentration CI2 being low, high crystal quality can be obtained in the second nitride region 62.

As shown in FIG. 2, the first interface region 61ar including the first interface 61a includes the second peak position p2 in the first direction D1. In the embodiment, the carbon concentration profile along the first direction D1 in the stacked body 60S may have a carbon peak value Cpk at a second peak position p2. The second peak position p2 is the position of the first interface 61a or a position near the first interface 61a. It is considered that the high carbon concentration C (C) at the first interface 61a (the second peak position p2) makes it easier for chlorine to be efficiently taken into the silicon surface, for example. Thereby, the formation of a SiN region on the silicon surface is more effectively suppressed. The second peak position p2 may be substantially the same as the first peak position p1. The distance along the first direction D1 between the second peak position p2 and the first peak position p1 may be 20 nm or less. This distance may be 10 nm or less.

The peak of the carbon concentration C (C) may be caused by, for example, carbon included in the source gas.

In the example of FIG. 2, the carbon peak value Cpk at the second peak position p2 is approximately 2.5×10²⁰/cm³. In the embodiment, the carbon peak value Cpk may be not less than 2×10²⁰/cm³ and not more than 3×10²⁰/cm³.

The carbon concentration C (C) may decrease sharply in the first nitride region 61. As already explained, the stacked body 60S includes the second interface 61b between the first nitride region 61 and the second nitride region 62. The first nitride region 61 includes the first position pZ1. The first position pZ1 is the center between the first peak position p1 and the second interface 61b in the first direction D1. The carbon concentration C (C) at the first position pZ1 is not less than 1/1000 times and not more than 1/100 times the carbon peak value Cpk.

The carbon concentration C (C) at the first position pZ1 is, for example, not less than 1×10¹⁷/cm³ and not more than 5×10¹⁷/cm³.

As already explained, the base 60 includes the second position pZ2. The direction from the second position pZ2 to the first position pZ1 is along the first direction D1. The distance d2 along the first direction D1 between the second position pZ2 and the first peak position p1 is the same as the distance d1 along the first direction D1 between the first peak position p1 and the first position pZ1. The carbon concentration CpZ1 at the first position pZ1 is lower than the carbon concentration CpZ2 at the second position pZ2. Thus, the carbon concentration C (C) may decrease more steeply in the first nitride region 61 than that in the base 60. Higher crystal quality is obtained in the first nitride region 61.

In the embodiment, the carbon peak value Cpk at the second peak position p2 may be not less than 10 times and not more than 500 times the carbon concentration C2 in the second nitride region 62.

The carbon concentration C2 in the second nitride region 62 may be higher than the carbon concentration C (C) (for example, carbon concentration CpZ1) in the first nitride region 61. For example, higher crystal quality can be easily obtained in the third nitride region 63 formed on the second nitride region 62. The concentration of carbon in the second nitride region 62 may be, for example, not less than 1×10¹⁸/cm³ and not more than 8×10¹⁸/cm³.

As shown in FIG. 2, the carbon concentration in the third nitride region 63 may be higher than the carbon concentration CpZ1 at the first position pZ1.

In the embodiment, a first thickness t1 (see FIG. 1) of the first nitride region 61 may be, for example, not less than 100 nm and not more than 300 nm. A second thickness t2 (see FIG. 1) of the second nitride region 62 may be, for example, not less than 100 nm and not more than 300 nm. These thicknesses are lengths in the first direction D1.

In the embodiment, a distance between the position of the first interface 61a in the first direction D1 and the first peak position p1 (the position in the first direction D1 where the chlorine peak value Clpk is obtained) may be, for example, ¼ or less of the first thickness t1. This distance may be substantially zero. The thickness (length in the first direction D1) of the first interface region 61ar including the first interface 61a may be, for example, ¼ or less of the first thickness t1.

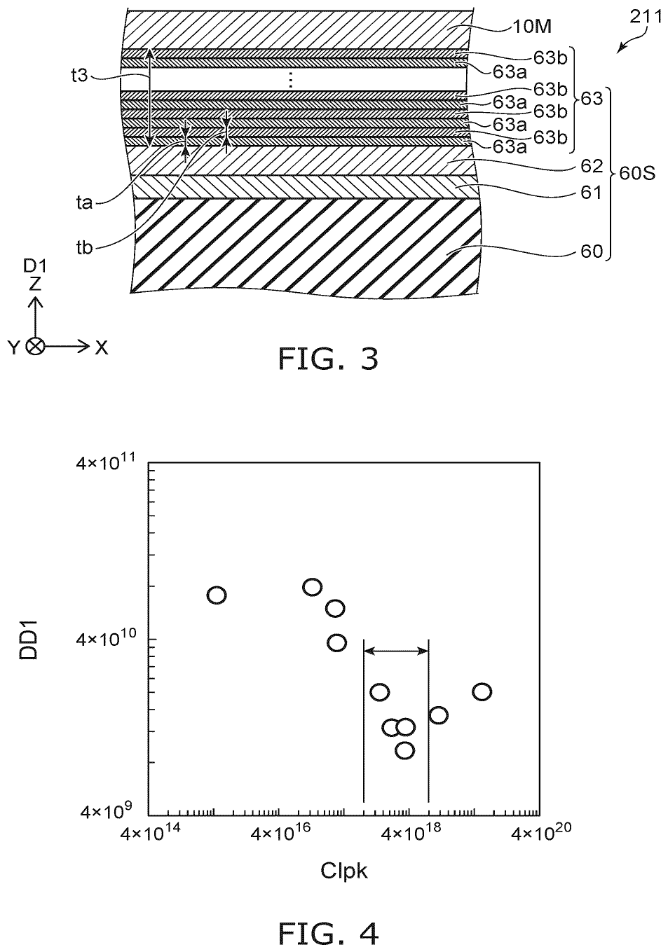

FIG. 3 is a schematic cross-sectional view illustrating a nitride structure according to the first embodiment.

As shown in FIG. 3, in a nitride structure 211 according to the embodiment, the stacked body 60S includes the third nitride region 63. The second nitride region 62 is provided between the first nitride region 61 and the third nitride region 63. The third nitride region 63 includes a plurality of first nitride films 63a including Al_{y1}Ga_{1-y1}N (0<y1≤1) and a plurality of second nitride films 63b including Al_{y2}Ga_{1-y2}N (0≤y2<1, y2<y1). The configuration of the nitride structure 211 except for this may be the same as the configuration of the nitride structure 210.

One of the plurality of first nitride films 63a is provided between one of the plurality of second nitride films 63b and another one of the plurality of second nitride films 63b in the first direction D1. One of the plurality of second nitride films 63b is provided between one of the plurality of first nitride films 63a and another one of the plurality of first nitride films 63a in the first direction D1. The third nitride region 63 is, for example, a superlattice layer. By the third nitride region 63, high crystal quality is easily obtained, for example. For example, dislocations are suppressed. For example, distortion is reduced.

As explained with reference to FIG. 2, in the nitride structure 211, the carbon concentration C3 in the third nitride region 63 may be higher than the carbon concentration CpZ1 at the first position pZ1. Thereby, it becomes easy to obtain high crystal quality in the nitride region (or nitride semiconductor layer, etc.) provided on the third nitride region 63.

As shown in FIG. 3, a semiconductor member 10M may be provided on the third nitride region 63. The semiconductor member 10M may include, for example, a GaN layer. The first nitride region 61, the second nitride region 62, and the third nitride region 63 function as a buffer layer.

A thickness ta of one of the plurality of first nitride films 63a may be, for example, not less than 3 nm and not more than 7 nm. A thickness tb of one of the plurality of second nitride films 63b may be, for example, not less than 20 nm and not more than 30 nm. A third thickness t3 of the third nitride region 63 may be, for example, not less than 3500 nm and not more than 4000 nm. These thicknesses are lengths in the first direction D1.

Hereinafter, examples of experimental results regarding nitride structures will be explained. In the experimental sample, the semiconductor member 10M (a GaN layer) is provided on the third nitride region 63. In the experiment, the pretreatment conditions of the film forming apparatus, the treatment conditions of the base 60, the conditions for forming the first nitride region 61, etc. are changed. In the experiment, crystal quality such as dislocation density in the semiconductor member 10M is evaluated.

FIG. 4 is a graph illustrating the characteristics of nitride structures.

The horizontal axis in FIG. 4 is the chlorine peak value Clpk at the first peak position p1. The vertical axis is the edge dislocation density DD1.

As shown in FIG. 4, the edge dislocation density DD1 being low is obtained when the chlorine peak value Clpk is not less than 2×10¹⁷/cm³ and not more than 2×10¹⁸/cm³. In the embodiment, the chlorine peak value Clpk is preferably not less than 2×10¹⁷/cm³ and not more than 2×10¹⁸/cm³.

When the chlorine peak value Clpk is less than 2×10¹⁷/cm³, the edge dislocation density DD1 is high. If the chlorine peak value Clpk is too low, it is considered that, for example, the formation of a SiN region on the silicon surface is not sufficiently suppressed.

When the chlorine peak value Clpk exceeds 2×10¹⁸/cm³, the edge dislocation density DD1 is high. If the chlorine peak value Clpk is too high, it is considered that, for example, it becomes difficult for the chlorine concentration C(Cl) to drop sufficiently steeply. Thereby, it becomes difficult for the chlorine concentration C(Cl) in the first nitride region 61 to become sufficiently low. Thereby, it is thought that crystal quality becomes insufficient.

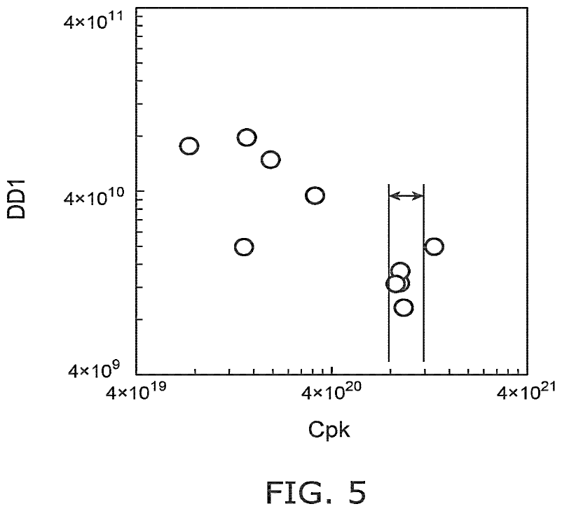

FIG. 5 is a graph illustrating the characteristics of the nitride structures.

The horizontal axis in FIG. 5 is the carbon peak value Cpk at the second peak position p2. The vertical axis is the edge dislocation density DD1.

As shown in FIG. 5, when the carbon peak value Cpk is not less than 2×10²⁰/cm³ and not more than 3×10²⁰/cm³, the edge dislocation density DD1 being low is obtained. In the embodiment, the carbon peak value Cpk is preferably not less than 2×10²⁰/cm³ and not more than 3×10²⁰/cm³.

When the carbon peak value Cpk is less than 2×10²⁰/cm³, the edge dislocation density DD1 is high. It is considered that if the carbon peak value Cpk is too low, the crystal quality in the first nitride region 61 tends to be insufficient.

When the carbon peak value Cpk exceeds 3×10²⁰/cm³, the edge dislocation density DD1 is high. It is considered that if the carbon peak value Cpk is excessively high, the crystal quality in the first nitride region 61 tends to be insufficient.

### Second Embodiment

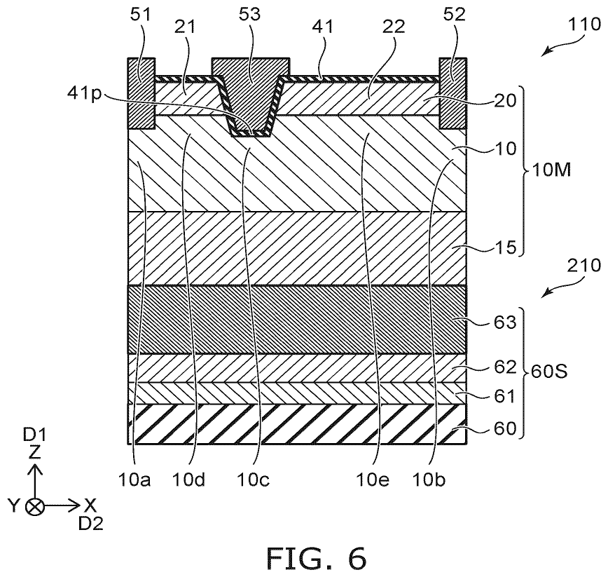

FIG. 6 is a schematic cross-sectional view illustrating a semiconductor device according to the second embodiment.

As shown in FIG. 6, a semiconductor device 110 according to the embodiment includes the nitride structure according to the first embodiment, the semiconductor member 10M, a first electrode 51, a second electrode 52, and a third electrode 53. In the semiconductor device 110, the nitride structure according to the first embodiment may be, for example, the nitride structure 210 or the nitride structure 211. A case where the semiconductor device 110 includes nitride structure 210 will be described.

The semiconductor member 10M includes a first semiconductor layer 10 including Alₓ₁Ga₁₋ₓ₁N (0≤x1<1) and a second semiconductor layer 20 including Alₓ₂Ga₁₋ₓ₂N (0<x2≤1, x1<x2). The composition ratio x1 is, for example, not less than 0 and not more than 0.15. The first semiconductor layer 10 may be, for example, a GaN layer. The composition ratio x2 is, for example, more than 0.15 and not more than 0.3. The second semiconductor layer 20 may be, for example, an AlGaN layer.

The first semiconductor layer 10 is provided between the stacked body 60S and the second semiconductor layer 20. As shown in FIG. 6, the semiconductor member 10M may further include a nitride layer 15. The nitride layer 15 is, for example, a GaN layer. A carbon concentration in the nitride layer 15 is higher than a carbon concentration in the first semiconductor layer 10. The nitride layer 15 may be provided as needed or may be omitted.

A second direction D2 from the first electrode 51 to the second electrode 52 crosses the first direction D1. The second direction D2 may be, for example, the X-axis direction. A position of the third electrode 53 in the second direction D2 is between a position of the first electrode 51 in the second direction D2 and a position of the second electrode 52 in the second direction D2.

The second semiconductor layer 20 includes a first semiconductor portion 21 and a second semiconductor portion 22. A direction from the first semiconductor portion 21 to the second semiconductor portion 22 is along the second direction D2. The first electrode 51 is electrically connected to the first semiconductor portion 21. The second electrode 52 is electrically connected to the second semiconductor portion 22.

Current flowing between the first electrode 51 and the second electrode 52 is controlled by a potential of the third electrode 53. The potential of the third electrode 53 may be, for example, a potential based on a potential of the first electrode 51. The first electrode 51 functions, for example, as a source electrode. The second electrode 52 functions as a drain electrode. The third electrode 53 functions as a gate electrode. The semiconductor device 110 is, for example, a transistor.

The first semiconductor layer 10 includes a region facing the second semiconductor layer 20. A carrier region is formed in this region. The carrier region is, for example, a two-dimensional electron gas. The semiconductor device 110 is, for example, a HEMT (High Electron Mobility Transistor).

The semiconductor device 110 includes the stacked body 60S of nitride structures 210 according to the first embodiment. Good crystallinity can be obtained in the semiconductor device 110. For example, the edge dislocation density DD1 being low can be obtained.

As shown in FIG. 6, in this example, at least a part of the third electrode 53 is provided between the first semiconductor portion 21 and the second semiconductor portion 22 in the second direction D2. The third electrode 53 is, for example, a recessed gate electrode.

For example, the first semiconductor layer 10 includes a first partial region 10a, a second partial region 10b, a third partial region 10c, a fourth partial region 10d, and a fifth partial region 10e. A direction from the first partial region 10a to the first electrode 51 is along the first direction D1. A direction from the second partial region 10b to the second electrode 52 is along the first direction D1. A direction from the third partial region 10c to the third electrode 53 is along the first direction D1.

A position of the fourth partial region 10d in the second direction D2 is between a position of the first partial region 10a in the second direction D2 and a position of the third partial region 10c in the second direction D2. A position of the fifth partial region 10e in the second direction D2 is between the position of the third partial region 10c in the second direction D2 and a position of the second partial region 10b in the second direction D2.

A direction from the fourth partial region 10d to the first semiconductor portion 21 is along the first direction D1. A direction from the fifth partial region 10e to the second semiconductor portion 22 is along the first direction D1. In this example, a part of the third electrode 53 is located between the fourth partial region 10d and the fifth partial region 10e in the second direction D2. A high threshold voltage can be obtained. For example, normally-off operation is obtained.

As shown in FIG. 6, the semiconductor device 110 may further include a first insulating member 41. The first insulating member 41 includes a first insulating portion 41p. The first insulating portion 41p is provided between the third electrode 53 and the semiconductor member 10M. The first insulating portion 41p functions, for example, as a gate insulating film.

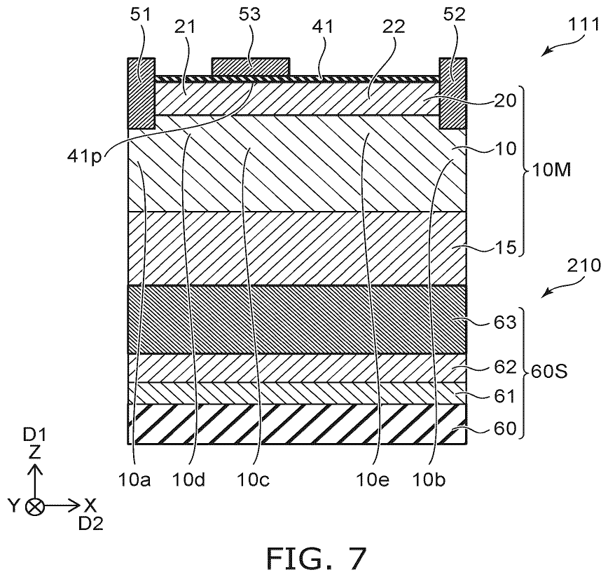

FIG. 7 is a schematic cross-sectional view illustrating a semiconductor device according to the second embodiment.

As shown in FIG. 7, a semiconductor device 111 according to the embodiment includes the nitride structure according to the first embodiment, the semiconductor member 10M, the first electrode 51, the second electrode 52, and the third electrode 53. In the semiconductor device 111, the third electrode 53 does not overlap the second semiconductor layer 20 in the second direction D2. The configuration of the semiconductor device 111 except for this may be the same as that of the semiconductor device 110.

In the semiconductor device 111, normally-on operation is obtained, for example. In the semiconductor device 111, the first insulating member 41 may be omitted. For example, the device may be used as a high frequency switching element.

In the embodiment, information regarding the shape of the nitride region, etc. is obtained, for example, from an electron microscope image. Information regarding the composition and element concentration in the nitride region can be obtained by, for example, EDX (Energy Dispersive X-ray Spectroscopy) or SIMS (Secondary Ion Mass Spectrometry). Information regarding the composition in the nitride region may be obtained, for example, by reciprocal space mapping. The first interface 61a may be determined, for example, based on information such as an electron microscope image, EDX, or SIMS.

Embodiments may include the following Technical proposals:
(Technical proposal 1)

A nitride structure, comprising:
a stacked body including
   a base including silicon,
   a first nitride region including AlN, and
   a second nitride region including Al_{z2}Ga_{1-z2}N (0≤z2<1),
the first nitride region being provided between the base and the second nitride region in a first direction,
the stacked body including a first interface region including a first interface between the base and the first nitride region,
the first interface region including a first peak position in the first direction, and
a chlorine concentration profile along the first direction in the stacked body having a chlorine peak value at the first peak position.
(Technical proposal 2)

The nitride structure according to Technical proposal 1, wherein
the chlorine peak value is not less than 2×10¹⁷/cm³ and not more than 2×10¹⁸/cm³.
(Technical proposal 3)

The nitride structure according to Technical proposal 1 or 2, wherein
the chlorine peak value is not less than 100 times and not more than 5000 times a concentration of chlorine in the second nitride region.
(Technical proposal 4)

The nitride structure according to Technical proposal 1 or 2, wherein
a concentration of chlorine in the second nitride region is 1×10¹⁵/cm³ or less.
(Technical proposal 5)

The nitride structure according to any one of Technical proposals 1-4, wherein
the stacked body includes a second interface between the first nitride region and the second nitride region,
the first nitride region includes a first position,
the first position is a center between the first interface and the second interface in the first direction, and
a concentration of chlorine at the first position is not less than 1/1000 times and not more than 1/100 times the chlorine peak value.
(Technical proposal 6)

The nitride structure according to Technical proposal 5, wherein
the concentration of chlorine in the first position is not less than 1×10¹⁴/cm³ and not more than 2×10¹⁵/cm³.
(Technical proposal 7)

The nitride structure according to any one of Technical proposals 1-4, wherein
the stacked body includes a second interface between the first nitride region and the second nitride region,
the first nitride region includes a first position,
the first position is a center between the first interface and the second interface in the first direction,
the base includes a second position,
a direction from the second position to the first position is along the first direction,
a distance along the first direction between the second position and the first peak position is the same as the distance along the first direction between the first peak position and the first position, and
a concentration of chlorine in the first position is lower than a concentration of chlorine in the second position.
(Technical proposal 8)

The nitride structure according to any one of Technical proposals 1-4, wherein
the first interface region includes a second peak position in the first direction, and
a carbon concentration profile along the first direction in the stacked body has a carbon peak value at the second peak position.
(Technical proposal 9)

The nitride structure according to Technical proposal 8, wherein
the carbon peak value is not less than 2×10²⁰/cm³ and not more than 3×10²⁰/cm³.
(Technical proposal 10)

The nitride structure according to Technical proposal 8 or 9, wherein
the carbon peak value is not less than 10 times and not more than 500 times a concentration of carbon in the second nitride region.
(Technical proposal 11)

The nitride structure according to Technical proposal 8 or 9, wherein
a concentration of carbon in the second nitride region is 1×10¹⁸/cm³ and not more than 8×10¹⁸/cm³.
(Technical proposal 12)

The nitride structure according to any one of Technical proposals 8-11, wherein
the stacked body includes a second interface between the first nitride region and the second nitride region,
the first nitride region includes a first position,
the first position is a center between the first interface and the second interface in the first direction, and
a concentration of carbon at the first position is not less than 1/1000 times and not more than 1/100 times the carbon peak value.
(Technical proposal 13)

The nitride structure according to Technical proposal 12, wherein
the concentration of carbon at the first position is not less than 1×10¹⁷/cm³ and not more than 5×10¹⁷/cm³.
(Technical proposal 14)

The nitride structure according to any one of Technical proposals 8-11, wherein
the stacked body includes a second interface between the first nitride region and the second nitride region,
the first nitride region includes a first position,
the first position is a center between the first interface and the second interface in the first direction,
the base includes a second location,
a direction from the second position to the first position is along the first direction,
a distance along the first direction between the second position and the first peak position is the same as a distance along the first direction between the first peak position and the first position, and
a concentration of carbon at the first position is lower than a concentration of carbon at the second position.
(Technical proposal 15)

The nitride structure according to Technical proposal 8 or 9, wherein
a concentration of carbon in the second nitride region is higher than a concentration of carbon in the first nitride region.
(Technical proposal 16)

The nitride structure according to Technical proposal 12 or 13, wherein
the stacked body further includes a third nitride region,
the second nitride region is between the first nitride region and the third nitride region,
the third nitride region includes:
   a plurality of first nitride films including Al_{y1}Ga_{1-y1}N (0<y1≤1), and
   a plurality of second nitride films including Al_{y2}Ga_{1-y2}N (0≤y2<1, y2<y1),
one of the plurality of first nitride films is between one of the plurality of second nitride films and another one of the plurality of second nitride films in the first direction, and
the one of the plurality of second nitride films is between the one of the plurality of first nitride films and another one of the plurality of first nitride films in the first direction.
(Technical proposal 17)

The nitride structure according to Technical proposal 16, wherein
a concentration of carbon in the third nitride region is higher than the concentration of carbon in the first position.
(Technical proposal 18)

A semiconductor device, comprising:
the nitride structure according to any one of Technical proposals 1-17;
a semiconductor member;
a first electrode;
a second electrode; and
a third electrode,
the semiconductor member including
   a first semiconductor layer including Alₓ₁Ga₁₋ₓ₁N (0≤ x1<1), and
   a second semiconductor layer including Alₓ₂Ga₁₋ₓ₂N (0<x2≤1, x1<x2),
the first semiconductor layer being provided between the stacked body and the second semiconductor layer,
a second direction from the first electrode to the second electrode crossing the first direction,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion, and
the second electrode being electrically connected to the second semiconductor portion.
(Technical proposal 19)

The semiconductor device according to Technical proposal 18, further comprising:
a first insulating member including a first insulating portion, and
the first insulating portion being provided between the third electrode and the semiconductor member.
(Technical proposal 20)

The semiconductor device according to Technical proposal 18 or 19, wherein
at least a part of the third electrode is provided between the first semiconductor portion and the second semiconductor portion in the second direction.

According to the embodiment, a nitride structure and a semiconductor device with improved characteristics can be provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

In the specification, “state of being electrically connected” includes a state in which a plurality of conductors are physically in contact with each other and a current flows between the plurality of conductors. The “state of being electrically connected” includes a state in which another conductor is inserted between the plurality of conductors and a current flows between the plurality of conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the nitride structure such as nitride regions, bases, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all nitride structures and all semiconductor devices practicable by an appropriate design modification by one skilled in the art based on the nitride structures and semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nitride structure, comprising:
a stacked body including
a base including silicon,
a first nitride region including AlN, and
a second nitride region including Al_{z2}Ga_{1-z2}N (0≤z2<1),
the first nitride region being provided between the base and the second nitride region in a first direction,
the stacked body including a first interface region including a first interface between the base and the first nitride region,
the first interface region including a first peak position in the first direction, and
a chlorine concentration profile along the first direction in the stacked body having a chlorine peak value at the first peak position.

2. The structure according to claim 1, wherein
the chlorine peak value is not less than 2×10¹⁷/cm³ and not more than 2×10¹⁸/cm³.

3. The structure according to claim 1, wherein
the chlorine peak value is not less than 100 times and not more than 5000 times a concentration of chlorine in the second nitride region.

4. The structure according to claim 1, wherein
a concentration of chlorine in the second nitride region is 1×10¹⁵/cm³ or less.

5. The structure according to claim 1, wherein
the stacked body includes a second interface between the first nitride region and the second nitride region,
the first nitride region includes a first position,
the first position is a center between the first interface and the second interface in the first direction, and
a concentration of chlorine at the first position is not less than 1/1000 times and not more than 1/100 times the chlorine peak value.

6. The structure according to claim 5, wherein
the concentration of chlorine in the first position is not less than 1×10¹⁴/cm³ and not more than 2×10¹⁵/cm³.

7. The structure according to claim 1, wherein
the stacked body includes a second interface between the first nitride region and the second nitride region,
the first nitride region includes a first position,
the first position is a center between the first interface and the second interface in the first direction,
the base includes a second position,
a direction from the second position to the first position is along the first direction,
a distance along the first direction between the second position and the first peak position is the same as the distance along the first direction between the first peak position and the first position, and
a concentration of chlorine in the first position is lower than a concentration of chlorine in the second position.

8. The structure according to claim 1, wherein
the first interface region includes a second peak position in the first direction, and
a carbon concentration profile along the first direction in the stacked body has a carbon peak value at the second peak position.

9. The structure according to claim 8, wherein
the carbon peak value is not less than 2×10²⁰/cm³ and not more than 3×10²⁰/cm³.

10. The structure according to claim 8, wherein
the carbon peak value is not less than 10 times and not more than 500 times a concentration of carbon in the second nitride region.

11. The structure according to claim 8, wherein
a concentration of carbon in the second nitride region is 1×10¹⁸/cm³ and not more than 8×10¹⁸/cm³.

12. The structure according to claim 8, wherein
the stacked body includes a second interface between the first nitride region and the second nitride region,
the first nitride region includes a first position,
the first position is a center between the first interface and the second interface in the first direction, and
a concentration of carbon at the first position is not less than 1/1000 times and not more than 1/100 times the carbon peak value.

13. The structure according to claim 12, wherein
the concentration of carbon at the first position is not less than 1×10¹⁷/cm³ and not more than 5×10¹⁷/cm³.

14. The structure according to claim 8, wherein
the stacked body includes a second interface between the first nitride region and the second nitride region,
the first nitride region includes a first position,
the first position is a center between the first interface and the second interface in the first direction,
the base includes a second location,
a direction from the second position to the first position is along the first direction,
a distance along the first direction between the second position and the first peak position is the same as a distance along the first direction between the first peak position and the first position, and
a concentration of carbon at the first position is lower than a concentration of carbon at the second position.

15. The structure according to claim 8, wherein
a concentration of carbon in the second nitride region is higher than a concentration of carbon in the first nitride region.

16. The structure according to claim 12, wherein
the stacked body further includes a third nitride region,
the second nitride region is between the first nitride region and the third nitride region,
the third nitride region includes:
a plurality of first nitride films including Al_{y1}Ga_{1-y1}N (0<y1≤1), and
a plurality of second nitride films including Al_{y2}Ga_{1-y2}N (0≤y2<1, y2<y1),
one of the plurality of first nitride films is between one of the plurality of second nitride films and another one of the plurality of second nitride films in the first direction, and
the one of the plurality of second nitride films is between the one of the plurality of first nitride films and another one of the plurality of first nitride films in the first direction.

17. The structure according to claim 16, wherein
a concentration of carbon in the third nitride region is higher than the concentration of carbon in the first position.

18. A semiconductor device, comprising:
the nitride structure according to claim 1;
a semiconductor member;
a first electrode;
a second electrode; and
a third electrode,
the semiconductor member including
a first semiconductor layer including Alₓ₁Ga₁₋ₓ₁N (0≤x1<1), and
a second semiconductor layer including Alₓ₂Ga₁₋ₓ₂N (0<x2≤1, x1<x2),
the first semiconductor layer being provided between the stacked body and the second semiconductor layer,
a second direction from the first electrode to the second electrode crossing the first direction,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion, and
the second electrode being electrically connected to the second semiconductor portion.

19. The device according to claim 18, further comprising:
a first insulating member including a first insulating portion, and
the first insulating portion being provided between the third electrode and the semiconductor member.

20. The device according to claim 18, wherein
at least a part of the third electrode is provided between the first semiconductor portion and the second semiconductor portion in the second direction.
